(19) United States
(12) Patent Application Publication
(10) Pub. No.: US 2005/0130431 A1
(43) Pub. Date: Jun. 16, 2005

(54) Method for making a package substrate without etching metal layer on side walls of die-cavity

(75) Inventors: Chia-Shang Chen, Hsinchu City (TW); Kuang-Hua Lin, Sinpu Township (TW); Chi-Jau Tzeng, Hsinchu City (TW); Jian-Ming Jiang, Ciaotou Township (TW)

Correspondence Address: TROXELL LAW OFFICE PLLC, SUITE 1404, 5205 LEESBURG PIKE, FALLS CHURCH, VA, 22041, US

(73) Assignee: Advanced Semiconductor Engineering Inc.

(21) Appl. No.: 10/733,272

(22) Filed: Dec. 12, 2003

(51) Int. Cl. H01L 21/311

(52) U.S. Cl. 438/694

(57) ABSTRACT

A method for making a package substrate without etching metal layer on side walls of a die-cavity is disclosed. At least a through slot is formed around a defined die-cavity region of a substrate so as to form a die-cavity portion in the die-cavity region. The through slot has side walls without cutting off the die-cavity portion. A metal layer is formed on the side walls inside the through slot. A dry film is attached on the substrate and the die-cavity portion so as to seal the side walls of the through slot. The metal layer on the side walls is reserved during etching. A die-cavity with metalized side walls is formed after removing the die-cavity portion.

### FIELD OF THE INVENTION

The present invention is relating to a method for making a semiconductor package substrate, particularly to a method for making a cavity down package substrate in order to prevent etching the metal layer on side walls of die-cavity.

### BACKGROUND OF THE INVENTION

The cavity down ball grid array package is commonly used in semiconductor package, which is abbreviated to cavity-down BGA package and had been brought up from U.S. Pat. No. 5,834,839 and No. 6,084,777. The cavity down BGA package is showed in FIG. 1. A circuit substrate 20 with a die-cavity 21 is adhered on a heat spreader 10. A semiconductor die 30 is attached on the heat spreader 10 in die-cavity 21. Normally a plurality of bonding wires 31 electrically connect the semiconductor die 30 and the circuit substrate 20. A package body 40 is formed in the die-cavity 21 to seal the die 30. A plurality of solder balls 23 are planted on the outer surface 22 of circuit substrate 20.

It is familiar that the circuit substrate 20 suitable for cavity down BGA package is a printed circuit board, such as glass fiber reinforced resin of FR-4 resin, FR-5 resin or BT resin having a single-layer or multi-layer of circuit pattern layer. Based on demand of signal transmission or circuit design, especially high speed demand, it is necessary to metalize side walls of die-cavity of the circuit substrate (not showed in the drawing) in order to increase ground potential connection to die. Usually, it is difficult to form metal layer on side walls of die-cavity during etching process of circuit substrate of semiconductor package. Gold plating process (GPP) is a familiar method for making circuit substrate with metalized side walls. At first, a die-cavity in rectangle shape is directly routed out from a circuit substrate. A copper layer is electroplated on the top and bottom surface of the circuit substrate and side walls of the die-cavity, then a dry film is covered. The dry film is exposed and developed to expose the preformed wiring location and side walls of die-cavity. A Ni—Au layer is electroplated on the foregoing exposed preformed wiring location and side walls of die-cavity, and the Ni—Au layer is used as an anti-etching protection layer after removing the dry film. Then, a solder resist is coated on the top and bottom surface. The Ni—Au layer is not only preformed on the metal layer of side walls of die-cavity but also formed on the exposing surface of entire wires on the top and bottom surface of circuit substrate by special electroplating method, so that manufacturing process will become more complicated at high cost.

### SUMMARY

The primary object of the present invention is to provide a method for making a package substrate without etching metal layer on side walls of die-cavity. At least a through slot is formed on a circuit substrate to form a die-cavity portion in a defined die-cavity region of the circuit substrate. An anti-etching layer is formed on the circuit substrate and the die-cavity region to seal the through slot for preventing the metal layer of side walls of die-cavity from be etched improperly in process.

The secondary object of the present invention is to provide a method for making package substrate without etching metal layer on side walls of die-cavity. The method includes two routing step to form a die-cavity with metalized side walls economically. In first routing step a plurality of through slots are formed around a die-cavity region to form a die-cavity portion. The die-cavity portion supports an anti-etching layer for sealing the through slots without etching a metal layer in the through slots.

According to the method for making package substrate without etching metal layer on side walls of die-cavity, at least a slender through slot such as linear slot or L-shaped slot about 0.1 mm˜4.0 mm in width is formed around a defined die-cavity region during executing a firstly routing step. The die-cavity portion is integrally connected with the circuit substrate in the die-cavity region. Thereafter, a metal layer is formed on the top surface of the circuit substrate and side walls of the through slot, and an anti-etching layer is formed on the metal layer. The anti-etching layer, such as dry film, is supported by the die-cavity portion to seal the through slot for avoiding that etching solution enters into the through slot to etch off the metal layer on side walls. Then, the second routing step of the circuit substrate is executed to cut off the die-cavity portion after removing the anti-etching layer. The circuit substrate has metal layer on side walls of die-cavity.

### DESCRIPTION OF THE DRAWINGS

FIG. 1 is a cross-sectional view illustrating conventional cavity down BGA package.

FIG. 2 is a cross-sectional view illustrating a provided cavity down BGA package in accordance with the present invention.

FIG. 3A to 3H are cross-sectional views of the substrate during making process in accordance with the method of the present invention for making a package substrate without etching metal layer on side walls of a die-cavity.

FIG. 4 is a perspective view of the substrate with slender through slots in accordance with the method of the present invention for making a package substrate without etching metal layer on side walls of a die-cavity.

FIG. 5 is a top view of the substrate with slender through slots in the second embodiment in accordance with the method of the present invention for making a package substrate without etching metal layer on side walls of a die-cavity.

FIG. 6 is a top view of the substrate with slender through slots in the third embodiment in accordance with the method of the present invention for making a package substrate without etching metal layer on side walls of a die-cavity.

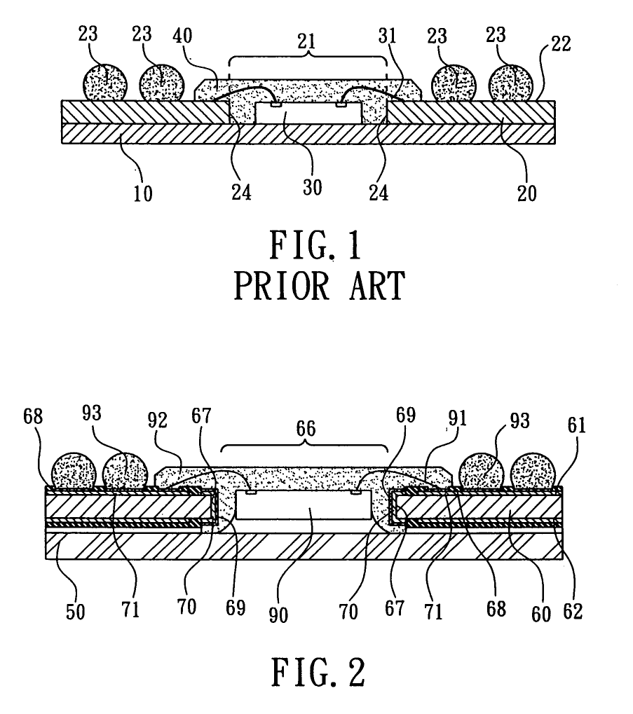

### DETAILED DESCRIPTION OF THE PRESENT INVENTION

Referring to the drawings attached, the present invention will be described by means of the embodiments below.

According to the present invention a method for making a package substrate without etching metal layer on side walls of a die-cavity is described as follows. As showed in FIG. 2, the package substrate is a circuit substrate such as a copper foil substrate based on glass fiber reinforced resin of FR-4, FR-5 or BT resin. The package substrate suitable for cavity down semiconductor package includes a substrate 60. The substrate 60 has a top surface 61, a bottom surface 62 and a die-cavity 66 passing through the top surface 61 and the bottom surface 62. A heat spreader 50 is attached on the bottom surface 62 of the substrate 60. The die-cavity 66 is a little bigger than a die 90 in size for accommodating the die 90. The die 90 is installed in the die-cavity 66 of the substrate 60, and the back surface of the die 90 is attached onto the heat spreader 50. A plurality of bonding wires 91 electrically connect bonding pads on active surface of the die 90 and circuit pattern 71 of the substrate 60. The circuit pattern 71 is formed on the top surface 61 of the substrate 60 and electrically connects a plurality of solder balls 93 on the top surface 61 with bonding wires 91. The solder balls 93 are made of lead-tin alloy or other conductive materials, such as conductive pins alternatively. Commonly, a package body 92 is formed in the die-cavity 66 by molding or potting method. A metal layer 70 is formed on the plurality of side walls 67 of die-cavity 66 on the substrate 60 such as copper plating layer and is electrically connected with the ground potential (not showed in the drawing) of the die 90 for eliminating signal interference between die 90 and substrate 60, and decreasing cross-talk. Preferably, there is a surface treating layer 69 such as Ni—Au layer covering on the metal layer 70 of the side walls 67 so as to prevent the metal layer 70 of the side walls 67 from oxidizing. Besides, an insulation cover layer 68, such as solder resist or cover layer, is formed on the top surface 61 of the substrate 60 and covers the circuit pattern 71.

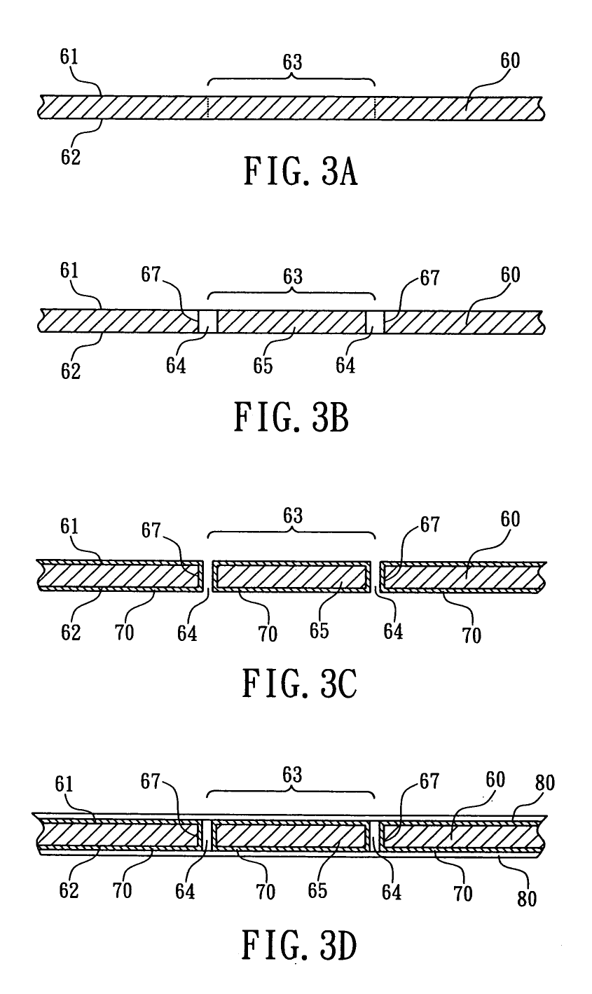

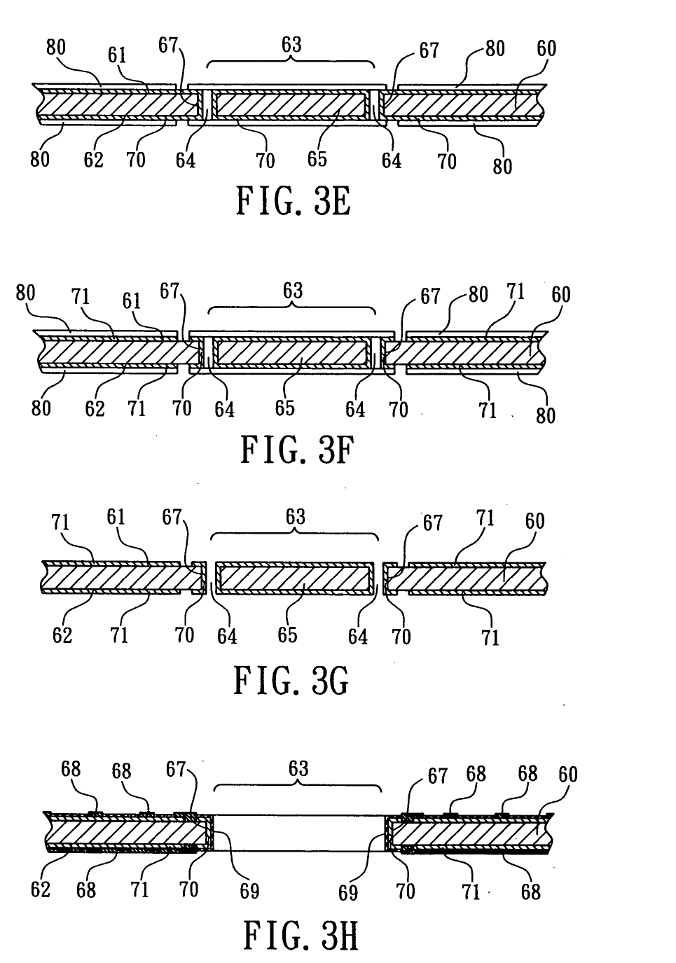

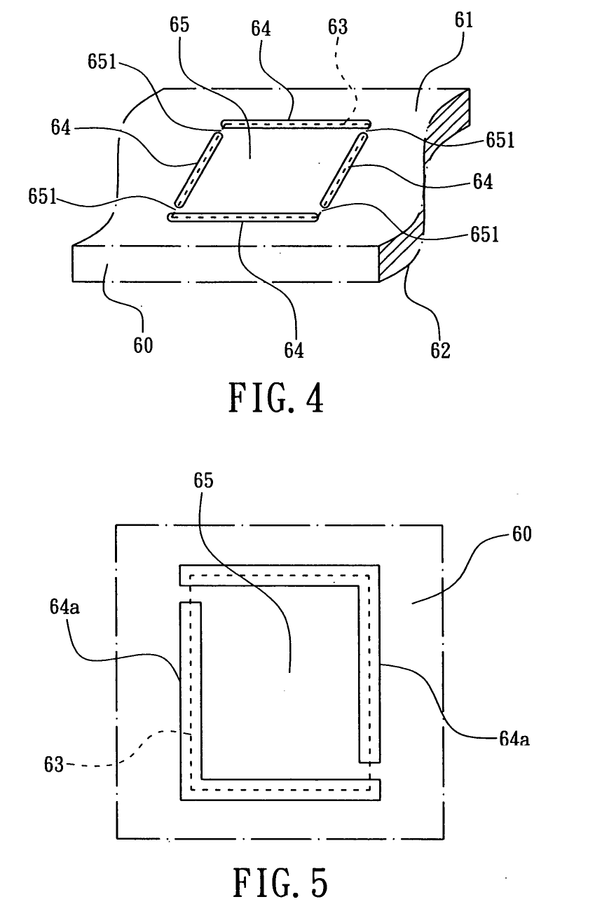

The process for making the package substrate mentioned above is showed from FIG. 3A to FIG. 3H. Initially, a substrate 60 is provided as showed in FIG. 3A. The substrate 60 has a top surface 61 and a bottom surface 62. The top surface 61 includes a defined die-cavity region 63 and a wiring region surrounding the die-cavity region 63, but not be a die cavity yet. The die-cavity region 63 is a little bigger than the die 90 in size. The substrate 60 may be a single-layer or multi-layer of printed circuit board. As showed in FIG. 3B and FIG. 4, at least a through slot 64 is formed around the die-cavity region 63 mentioned above by cutting, punching or routing method in a firstly routing step. In this embodiment, the through slots 64 are linear slots passing through the top surface 61 and the bottom surface 62 of the substrate 60 so as to form a die-cavity portion 65 that is integrally connected with the substrate 60 in the die-cavity region 63 of the substrate 60. The through slots have side walls 67 to be main part of side walls of the die cavity 66. The die-cavity portion 65 has at least a tie bar 651 to connect with the substrate 60. It is better that the width of the through slots 64 is between 0.1 mm and 4.0 mm to be slender enough. As showed in FIG. 3C, a metal layer 70 (such as copper, aluminum or gold) is formed on the top surface 61, bottom surface 62 of the substrate and the side walls 67 inside through slot 64 by a method selected from electroplating, electroless plating, evaporation, sputtering, and deposition. Thereafter, as showed in FIG. 3D, an anti-etching layer 80 is formed on the metal layer 70. In this embodiment, the anti-etching layer 80 is a photosensitive dry film. The anti-etching layer 80 is attached on the top surface 61, bottom surface 62 and the die-cavity portion 65 also be affixed above the through slots 64 so that the anti-etching layer 80 can seal the side walls 67 (through slots 64) in a water-proof condition. The metal layer 70 on the side walls 67 inside the through slots 64 is well protected from being etched off. As showed in FIG. 3E, the anti-etching layer 80 is patterned by exposure and development technologies to become a patterned anti-etching layer 80. The patterned anti-etching layer 80 covers the circuit predetermined area of the metal layer 70 and also seals the through slots 64. Further as showed in FIG. 3F, the patterned anti-etching layer 80 is used as an etching mask without exposing the through slots 64 for forming a circuit pattern layer 71 on the top surface 61 or the bottom surface 62 of the substrate 60 by etching the metal layer 70. The through slots 64 are covered by the patterned anti-etching layer 80 during etching so that etching solution like iron chloride or copper chloride solution will not enter the through slot 64. The metal layer 70 on the side walls 67 inside through slot 64 will be reserved through the etching process. As showed in FIG. 3G, then the patterned anti-etching layer 80 is removed. Finally, as shown in FIG. 3H and FIG. 4, the die-cavity portion 65 is removed along the tie bars 651 of the substrate 60 in a secondly routing step. An insulation cover layer 68 such as solder resist or cover layer is formed on the top surface 61 of the substrate 60 and the circuit pattern layer 71 by spraying, printing or laminating method to complete making the package substrate as showed in FIG. 2. Preferably, a surface treating layer 69 like Ni—Au layer is formed on the metal layer 70 of the side walls 67 by plating method to prevent the metal layer 70 of side walls 67 from oxidizing. A die-cavity 66 with metalized side walls 67 is formed in the circuit substrate 60 for accommodating die. The metal layer 70 with discontinuous configuration is formed on the side walls 67 of the die-cavity 66 and will not be etched off.

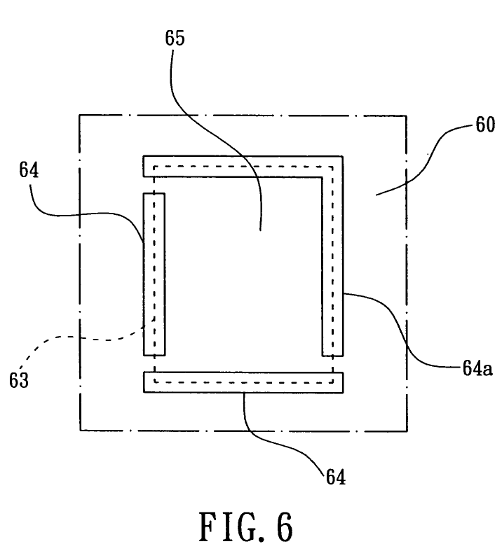

According to the method of the present invention for making package substrate without etching metal layer on side walls of die-cavity, to replace the linear shape the through slots 64 being formed in the step of forming through slot 64 L-shaped through slots 64a also may be formed around the defined die-cavity region 63 of the substrate 60 as showed in FIG. 5. May both linear through slot 64 and L-shaped through slot also can be formed simultaneously as showed in FIG. 6, or U-shaped through slot also can be formed (not showed in the drawing).

The above description of embodiments of this invention is intended to be illustrated and not limiting. Other embodiments of this invention will be obvious to those skilled in the art in view of the above disclosure.

1. A method for making a package substrate comprising the steps of:
providing a substrate having a top surface and a bottom surface;
forming at least a through slot passing through the top surface and the bottom surface of the substrate so as to form a plurality of side walls inside the through slot and a die-cavity portion;
forming a metal layer on the top surface of the substrate and the side walls inside the through slot;
forming an anti-etching layer on the top surface of the substrate and the die-cavity portion for sealing the through slot;
patterning the anti-etching layer;
etching the metal layer on the top surface of the substrate to form a circuit pattern under the anti-etching layer, the anti-etching layer preventing the metal layer on the side walls of the through slot from etched;
removing the anti-etching layer; and
removing the die-cavity portion of the substrate to form a die-cavity of the substrate having the metal layer on the side walls.

2. The method in accordance with claim 1, wherein the anti-etching layer is a photosensitive dry film.

3. The method in accordance with claim 1, wherein the through slot has a width between 0.1 mm and 4.0 mm.

4. The method in accordance with claim 1, wherein the metal layer on the side walls is in discontinuous configuration after the step of removing the die-cavity portion.

5. The method in accordance with claim 1, wherein the through slot is a linear slot.

6. The method in accordance with claim 1, wherein the through slot is a L-shaped slot.

7. The method in accordance with claim 1, further comprising a step of forming an insulation cover layer on the circuit pattern layer.

8. The method in accordance with claim 1, further comprising a step of forming a surface treating layer on the metal layer.

9. A method for making a package substrate comprising the steps of:
providing a substrate having a top surface and a bottom surface, the top surface including a die-cavity region;
forming at least a slot around the die-cavity region so as to form a plurality of side walls inside the slot and a die-cavity portion within the die-cavity region, wherein the die-cavity portion is integrally connected with the substrate;
forming a metal layer on the top surface of the substrate and the side walls;
forming an anti-etching layer on the top surface of the substrate and the die-cavity portion for sealing the slot;
patterning the anti-etching layer;
etching the metal layer on the top surface of the substrate, the anti-etching layer preventing the metal layer on the side walls of the through slot from be etched;
removing the anti-etching layer; and
removing the die-cavity portion of the substrate to form a die-cavity of the substrate having the metal layer on the side walls.

10. The method in accordance with claim 9, wherein the anti-etching layer is a photosensitive dry film.

11. The method in accordance with claim 9, wherein the slot has a width between 0.1 mm and 4.0 mm.

12. The method in accordance with claim 9, wherein the metal layer on the side walls is in discontinuous configuration after the step of removing the die-cavity portion.

13. The method in accordance with claim 9, wherein the slot is a linear slot.

14. The method in accordance with claim 9, wherein the slot is a L-shaped slot.

15. The method in accordance with claim 9, further comprising a step of forming an insulation cover layer on the circuit pattern layer.

16. The method in accordance with claim 9, further comprising a step of forming a surface treating layer on the metal layer.

17. A method for making a package substrate comprising the steps of:
providing a substrate having a top surface and a bottom surface, the top surface including a die-cavity region;
firstly routing the substrate to form a plurality of slots around the die-cavity region so as to form a die-cavity portion integrally connected with the substrate within the die-cavity region;
forming a metal layer in the slots; and
secondly routing the substrate to connect the slots in a manner that the die-cavity portion is separated from the substrate.

18. The method in accordance with claim 17, wherein the slots have a width between 0.1 mm and 4.0 mm.

19. The method in accordance with claim 17, wherein the slots are linear slots.

20. The method in accordance with claim 17, wherein the slots are L-shaped slots.
